(19) United States
(12) Patent Application Publication
(10) Pub. No.: US 2016/0327626 A1
(43) Pub. Date: Nov. 10, 2016

(54) CALIBRATION OF LARMOR FREQUENCY DRIFT IN NMR SYSTEMS

(71) Applicant: PRESIDENT AND FELLOWS OF HARVARD COLLEGE, Cambridge, MA (US)

(72) Inventor: DONGWAN HA, Cambridge, MA (US)

(73) Assignee: PRESIDENT AND FELLOWS OF HARVARD COLLEGE, Cambridge, MA (US)

(21) Appl. No.: 15/109,440

(22) PCT Filed: Jan. 26, 2015
(86) PCT No.: PCT/US15/12845

§ 371 Date: Jun. 30, 2016

Related U.S. Application Data
(60) Provisional application No. 61/932,383, filed on Jan. 28, 2014.
(60) Provisional application No. 62/022,151, filed on Jul. 8, 2014.

(51) Int. Cl. G01R 33/58; G01R 33/44

(52) U.S. Cl. CPC G01R 33/58; G01R 33/443

(57) ABSTRACT

A calibration system is configured to remove in an f₂ frequency domain the effects of a fluctuation ΔΩ(t) in the Larmor frequencies of a plurality of nuclear spins in a sample, from an NMR signal acquired from the sample during an acquisition time t₂ of an NMR scan having an evolution time t₁. In this way, the calibration system generates an f₂-calibrated NMR signal. The calibration system is further configured to remove from the f₂-calibrated NMR signal the effects of ΔΩ(t) in an f₁ domain, thereby additionally calibrating the f₂- calibrated NMR signal in the f₁ domain.

### CROSS-REFERENCE TO RELATED APPLICATIONS

This application is based upon, and claims the benefit of priority under 35 U.S.C. §119(e) from U.S. Provisional Patent Application Ser. No. 61/932,383 (“the '383 provisional application”), filed Jan. 28, 2014, entitled “Calibration of Larmor Frequency Drift in NMR Systems”; and from U.S. Provisional Patent Application Ser. No. 62/022,151 (the “'151 provisional application”), filed Jul. 8, 2014, entitled “Calibration of Non-Constant Larmor Frequency Drift in NMR Systems”. The contents of these provisional applications are incorporated herein by reference in their entireties as though fully set forth.

### BACKGROUND

In recent years, innovations such as homogeneous in-situ/ex-situ portable permanent magnets and highly integrated thus scalable NMR (nuclear magnetic resonance) spectrometer electronics have opened up possibilities for use of NMR spectroscopy in portable applications.

One problem, however, is that the magnetic field of the above permanent magnets remains unstable, despite superb spatial field homogeneity. This is because the constituent ferromagnetic materials have considerable temperature dependency in their remanent magnetization, e.g. −1200 ppm/K for NdFeB at room temperature. Such large temperature dependency keeps their magnetic field drifting in accordance with the temperature fluctuation of the surrounding environment. This problem has been raised as one roadblock towards portable NMR spectroscopy. Generally, tight thermal insulation and temperature regulation are required, in order to achieve the requisite magnetic field stability over a long period of time, which is a requisite for NMR spectroscopy, especially multi-dimensional spectroscopy.

Because the field of these permanent magnets typically exhibits such appreciable temperature dependency, the Larmor frequencies of the spins in an NMR sample also usually exhibit temporal drifts, as the temperature fluctuates with time. The quality of the spectra from both 1D (one-dimensional) and 2D (two-dimensional) NMR spectroscopy is thereby degraded. The effect of the field fluctuations is pronounced in long-term experiments, from a few minutes to several hours. These include multiple-scan 1D NMR spectroscopy (e.g., for signal averaging), and 2D NMR spectroscopy where multiple scans are of algorithmic necessity for the signal sampling in the indirect frequency (f₁) domain. Furthermore, in 2D NMR spectroscopy, the field fluctuation effect also impacts on the spin evolution during the evolution phase (t₁). In other words, both the direct frequency (f₂) domain and the indirect frequency (f₁) domain of 2D NMR spectra are affected by field fluctuations.

### BRIEF DESCRIPTION OF THE DRAWINGS

FIG. 1 is a schematic flow chart of a method of Larmor frequency drift calibration, in accordance with some embodiments of the present application.

FIG. 2A provides a flowchart for a method of performing Larmor frequency drift calibration in the f₁ domain, in accordance with some embodiments of the present application.

FIG. 2B provides a table of f₁-calibration factors.

FIGS. 3A-3B show the simulation results of calibration for the 0^{th} order (constant) Larmor frequency drift ΔΩ₀.

FIGS. 4A-4D show the simulation results of Larmor frequency drift calibration for the non-constant term ΔΩ₁t.

FIGS. 5A-5D illustrate the results of Larmor frequency drift calibration of ΔΩ₀ for 1D NMR spectra of ethanol.

FIGS. 6A-6C illustrate the results of Larmor frequency drift calibration of the non-constant term ΔΩ₁t for 1D NMR spectra of ethanol.

FIGS. 7A-7C illustrate the results of applying Larmor frequency drift calibration for ΔΩ₀ to 2D COSY performed on an ethanol sample under the influence of the field fluctuations.

### DETAILED DESCRIPTION

In the present application, calibration methods and systems are disclosed that remove the effects of the magnetic field fluctuations in NMR spectroscopy using digital signal processing, without need for cumbersome temperature regulation for the magnet. Calibration methods and systems for magnetic field drift are discussed below in terms of 1D and 2D NMR. It will be readily understood by those skilled in the art that these methods and systems can be easily generalized to 3D NMR. Illustrative embodiments are discussed in this application. Other embodiments may be used instead. Many other related embodiments are possible.

As well known, in 2D NMR an evolution period and a mixing period are introduced between the preparation period and the acquisition period. The process of evolution lasts for a period of time labeled t₁, referred to as the evolution time t₁ or indirect time t₁. The evolution period introduced an indirectly-detected frequency dimension f₁, where f₁ is a Fourier transform of t₁. During the mixing period, coherence is transferred from one spin to another.

In the present application, the terms “evolution time,” “t₁”, and “indirect time” all have the same meaning, and are used interchangeably. In the present application, the terms “acquisition time,” t₂”, and “direct time” have the same meaning, and are used interchangeably.

In 2D NMR, data acquisition involves a series of scans with various values of t₁, where t₁ is typically incremented by a specific amount at each successive scan. During each scan, a pulse sequence excites the nuclei in the NMR sample, and the resulting FID (free induction decay) of the nuclei is received by the NMR spectrometer. Because t₁ is changed continuously, a series of different FIDs are received. This process is repeated until enough data is obtained for analysis using 2D Fourier transform. The series of FIDs are Fourier-transformed, first with respect to t₂, then with respect to t₁, so as to obtain a resulting 2D NMR spectrum.

When plotting a 2D NMR spectrum, two frequency axes are typically used to represent a chemical shift or other variable of interest. Each frequency axis is associated with one of the two time variables, namely: 1) the length t₂ of the evolution period; and 2) the time t₂ elapsed during the acquisition period. Both time variables can be converted from a time series to a frequency series through respective Fourier transforms. As explained above, 2D NMR experiments are typically performed as a series of scans, each scan recording the entire duration of the acquisition time, with a different specific evolution time in successive scans. The resulting plot shows an intensity value for each pair of frequency variables.

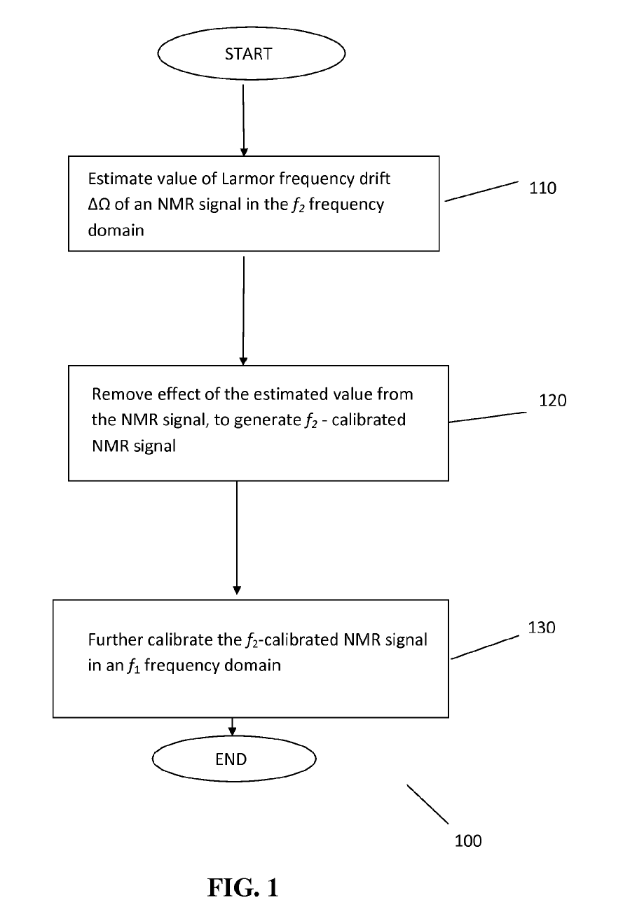

FIG. 1 is a schematic flow chart of a method 100 of calibration of Larmor frequency drift ΔΩ(t), in accordance with some embodiments of the present application. The method 100 includes an act 110 of estimating the value of the Larmor frequency drift ΔΩ(t) of an NMR signal in the f₂ domain. The method 100 further includes an act 120 of removing from the NMR signal the effect of the estimated value of the fluctuation, to generate an f₂-calibrated NMR signal. For example, in some embodiments the effect of the estimated fluctuation may be removed by multiplying a cancelling factor, as further described below Other embodiments may use different methods for removing the effect of the estimated fluctuation. The method 100 includes an additional act 130 of further calibrating the f₂-calibrated NMR signal in the f₁-domain. It should be noted that act 130 is only relevant to 2D NMR. As a result of act 130, an NMR signal for 2D NMR is generated that is calibrated in both the f₁-domain and f₂-domain.

In the present application, a calibration system is described that is configured to carry out the acts schematically illustrated in FIG. 1. In general, the portable experimental setup for NMR typically includes a permanent magnet (naturally exposed to the surrounding environment without thermal regulation), a capillary tube to carry the target sample to the sensitive volume, a solenoidal NMR coil wrapped around the capillary tube, and an NMR spectrometer electronics to generate pulse sequences and acquire NMR signals.

The calibration system may be included or integrated within the NMR spectrometer electronics, for example part of a processing system in the NMR spectrometer electronics. Alternatively, it may be part of a separate processing system that is responsive to user input to send control commands to the spectrometer electronics so as to calibrate the NMR signals.

The mathematical background for, and full details of, the above-mentioned calibration methods and systems are now described. An NMR analyte or sample typically consists of a plurality N of NMR-active nuclear spins (by way of example, ¹H spins), where individual spins can be indexed by a summation index k (1, 2, 3, . . . , N). The permanent magnet's field can be written as a sum B₀+ΔB₀(t), where B₀ represents the intended static field B₀, namely the static field B₀ in the absence of temporal fluctuations, and ΔB₀(t) represents the temporal fluctuation ΔB₀(t). The Larmor frequency Ωₖ(t) for the k-th spin can then be approximated to the first order as:

Ωₖ(t)=γ(1+δₖ)·(B₀+ΔB₀(t))+εₖ≅γB₀(1+δₖ)+εₖ+γΔB₀(t)=Ω_{0,k}+ΔΩ(t), (1)

where γ represents the gyromagnetic ratio, δₖ represents the chemical shift for the k-th spin, εₖ represents the frequency offset due to J-coupling, Ω_{0,k}≡γB₀(1+δₖ)+εₖ represents the intended Larmor frequency (i.e., the Larmor frequency in the absence of field fluctuations), and ΔΩ(t)≡γΔB₀(t) represents the frequency component that temporally drifts due to the field fluctuation.

It is noted that ΔΩ(t) is identical among all spins to the first order. ΔΩ(t) can influence certain 1D NMR experiments, where multiple scans over a long time are needed to enhance the SNR (signal-to-noise ratio). On the other hand, the ΔΩ(t) effect is significant in practically all 2D NMR experiments, because they inherently take a long time (typically on the order of several tens of minutes) with multiple scans being the algorithmic essence of 2D NMR regardless of the SNR. Therefore, ΔΩ(t) needs to be calibrated out to attain high-resolution NMR spectra, in particular in 2D and higher-D NMR.

In some embodiments of the present application, it may be assumed that the frequency drift term ΔΩ(t) in Eq. (1) takes a certain polynomial function of time: ΔΩ(t)=ΔΩ₀+ΔΩ₁t+ΔΩ₂t² . . . . While the constant frequency drift term ΔΩ₀ only shifts the NMR spectra from a reference frequency, the non-constant frequency drift term, ΔΩ₁t+ΔΩ₂t² . . . , distorts the amplitudes and phases of the NMR spectra. This distortion effect essentially spread out the NMR spectrum, thereby increasing its entropy.

An assumption may be made that ambient temperature does not change rapidly so that chemical shifts do not alter significantly. Also, the fluctuation of the magnetic field is slow compared to the fluctuation of surrounding temperature due to the heat capacity of the magnet and finite thermal contact with the surrounding. This mechanism can be understood as low-pass filtering of the surrounding temperature fluctuation, or Brownian motion of sizable particles.

Based on these observations, the following assumptions are made about the frequency fluctuation ΔΩ(t):

The difference between two adjacent observations of the field, ΔΩ(t+Δt)−ΔΩ(t), may have a probability density with its mean zero and its variance proportional to the temperature coefficient of the magnet, the thermal conductance to the surroundings, the variance of the surrounding temperature fluctuation, and the observation time difference Δt.

ΔΩ(t) is a slowly varying function and the acquisition time t is usually smaller than 1 s, thus higher order terms may be discarded, i.e.:

ΔΩ(t)≈ΔΩ₀+ΔΩ₁t (2)

Under the influence of such a field fluctuation, an NMR signal y(t) acquired by a quadrature receiver, thus phase sensitive, may be written as:

$$\begin{matrix}y ( t ) = {\sum }_{k}^{N} {c}_{k} exp \{ ( {iΩ}_{k} ( t ) - {λ}_{k} ) t \} \\ = exp \{ iΔΩ ( t ) t \} \times {\sum }_{k}^{N} {c}_{k} exp \{ ( {iΩ}_{0 , k} ( t ) - {λ}_{k} ) t \} \\ = w ( t ) \times x ( t ) ,\end{matrix} \qquad ( 3 )$$

where x(t) is an unaffected NMR signal, w(t) is a phase-modulation function of ΔΩ(t), cₖ is a complex amplitude representing the signal strength and phase, and λₖ is an exponential decay rate due, for instance, to spin-spin relaxation for the k-th spin.

Since w(t) modulates the frequencies and phases of y(t), its effect negatively impacts on the spectral distribution of nuclear spin energy (in other words, on the frequency domain representation of y(t)). Thus, in this application w(t) will be estimated, then its negative effect will be removed by correlating or examining the spectral distribution.

The Fourier transform of y(t), namely Y(ω), can represent the spectral distribution to some extent. Since it is complex valued, one can take the real part or imaginary part of Y(ω). Whether the real or the imaginary part is taken, however, it would not faithfully represent the spectral distribution because it may have negative peaks or dispersive peak shapes. The magnitude |Y(ω),| of Y(ω), or its energy spectral density |Y(ω)|² may represent the spectral distribution.

In some embodiments, the energy spectral density is used. One reason for this choice is that it represents correct peak shapes (Lorentzian) although it does not have correct peak intensities due to the square operation. The energy spectral density is normalized to obtain a probability density f_{Y}(ω):

$${f}_{Y} ( ω ) = \frac{{\vert Y ( ω ) \vert}^{2}}{{\int }_{- ∞}^{∞} {\vert Y ( ω ) \vert}^{2} d ω / 2 π} = \frac{{\vert ( W * X ) ( ω ) \vert}^{2}}{{\int }_{- ∞}^{∞} {\vert ( W * X ) ( ω ) \vert}^{2} d ω / 2 π} , \qquad ( 4 )$$

where Y(ω), W(ω) and X(ω) are the Fourier transforms of y(t), w(t), and x(t), respectively, and is the convolution operator.

Estimation of the Frequency Fluctuation ΔΩ(t)

Equation (2) contains two unknown variables: one is a constant frequency drift term, ΔΩ₀, and the other is a non-constant frequency modulation term ΔΩ₁t. The constant term ΔΩ₀ shifts the precession frequencies altogether away from their reference frequencies. The linear term ΔΩ₁t modulates the phase of the acquired signal and distorts peak shapes of its frequency-domain spectrum.

In order to estimate the value of ΔΩ₁in equation (2), one can ignore ΔΩ₀ in (2) and assume w(t) is a function of only ΔΩ₁t: i.e., w(t)=exp(iΔΩ₁t). If w(t) is not 1 (ΔΩ₁ is not zero), its Fourier transform W(ω) is different from a Dirac delta function; thus, its convolution with X(ω) spreads out the spectral distribution (Y(ω)=W(ω)*X(ω)). In other words, it makes the distribution more uniform and thus increases ‘the amount of uncertainty’ in observing the nuclear spin energies. The information entropy in information theory, h(f_{Y}(ω))=−∫f_{Y}(ω)ln f_{Y}(ω)dω/2π, serves as a great measure for such increase, where f_{Y}(ω) is a probability density defined in (4). Thus, this entropy may be used as a likelihood function to estimate ΔΩ₁.

Concretely, we estimate the maximally likely ΔΩ₁ by finding the minimum entropy of a probability density of y(t)·w⁻¹(t) where w(t)=exp(iΔΩ₁t). This estimation procedure can be written as:

$$Δ {\hat{Ω}}_{1} = arg {min}_{{ΔΩ}_{1}} h ( {f}_{Y \text{:} {ΔΩ}_{1}} ( ω ) ) \qquad ( 5 )$$

where f_{Y; ΔΩ}_{₁}^{(ω)} is the probability density for y(t)·w⁻¹(t) with w(t)=exp(iΔΩ₁t).

After the calibration of non-constant frequency drift ΔΩ₁t is performed, one can estimate the value of the constant frequency drift ΔΩ₀ by measuring the statistical distance of the probability density of a measured signal f_{Y}(ω) from a certain reference signal (one can choose one signal out of multiple-scan signals as a reference signal). The rationale behind this process is that the probability density for y(t) in independent experiments has the identical frequency-domain pattern in terms of relative peak positions, although the amplitudes of the peaks may vary according to the applied pulse sequences. In other words, this relative peak position pattern is a unique feature of a given NMR sample.

In some embodiments, the statistical distance of the probability density (calculated as in (4)) of the measured signal from that of the reference is measured, while shifting the frequency of the measured signal. Eventually, ΔΩ₀ is found when the statistical distance becomes minimum. To measure the statistical distance, a number of functions can be used, including without limitation f-divergences (e.g. relative entropy), Hellinger distance, distance correlation, and the inverse of the Pearson product-moment coefficient. As for the reference signal, a free induction decay signal is ideal as it does not have the amplitude modulation of the peaks during the coherence evolution that could attenuate individual peak's signal strength.

The above process can be written mathematically as:

$$Δ {\hat{Ω}}_{0} = arg {min}_{{ΔΩ}_{0}} D ( {f}_{Y ; {ΔΩ}_{0}} ( ω ) , {f}_{{X}_{R}} ( ω ) ) \qquad ( 6 )$$

where D(·,·) is a distance measuring function, f_{Y,ΔΩo}(ω) and f_{X}_{_{R}}(ω) are the probability densities for the measured signal y(t) with its frequency drifted by −ΔΩ₀ and the reference signal x_{R}(t), respectively, and the hat symbol signifies estimation.

A. Calibration of Larmor Frequency Drift in the f₂ Domain

As explained previously, the f₂ (or direct frequency) domain corresponds to the acquisition phase of an experiment, and is related to the time variable t₂. While this term is generally used for 2D NMR spectroscopy where t and t₁ respectfully correspond to the direct (f₂) and indirect (f₁) frequency domains, in the present application this term (f₂ domain) will be used to represent the frequency domain of 1D NMR as well.

The effect of the estimated frequency fluctuation, set forth above, can be removed to yield the correct signal x(t) by multiplying y(t) (Eq. (3)) by the estimated phase-modulation function ŵ⁻¹(t)=exp(−iΔ\hat{Ω}(t)t):

$$\begin{matrix}\hat{x} ( t ) = y ( t ) \times {\hat{w}}^{- 1} ( t ) \\ = {\sum }_{k}^{N} {c}_{k} exp \{ ( {iΩ}_{0 , k} - {λ}_{k} ) t \} .\end{matrix} \qquad ( 7 )$$

The application of the above methods can be further expanded for higher-order non-constant terms (e.g. ΔΩ₂ t²). For example, in order to calibrate out the effect of both ΔΩ₁t and ΔΩ₂ t², one can use the entropy minimization technique described above for both terms.

B. Calibration of Larmor Frequency Drift in the Indirect Frequency (f₁) Domain

In 2D NMR experiments, the field fluctuation also influences the indirect frequency (f₁) domain, which corresponds to the evolution phase lasting over time t₁. As described earlier, t₁ is varied at each scan. In one or more embodiments, frequency drift calibration is then performed in the indirect frequency (f₁) domain.

In overview, in some embodiments frequency drift calibration in the f₁ domain is performed by: obtaining a cosine modulation and a sine modulation in the complex amplitudes by respectively different tuning of the phase of an RF pulse sequence applied to the sample during the NMR scan; estimating the frequency offsets and in the cosine modulated and sine modulated amplitudes; and using the estimated frequency offsets to recover the complex amplitudes of an NMR signal that is calibrated in both the f₁ and f₂ domains.

The mathematical details for the f₁ frequency drift calibration, schematically set forth in paragraph [060] above, are now described. During the evolution phase, the complex amplitude cₖ of Eq. (3) is affected by the temporal field fluctuation. The complex amplitude cₖ can be written as:

$${c}_{k} = {\sum }_{j}^{N} {d}_{jk} cos \{ ( {Ω}_{0 , j} + ΔΩ ( t ) ) {t}_{1} + {φ}_{jk} \} , \qquad ( 8 )$$

where the cosine modulation can be readily attained by tuning the phase of a given pulse sequence. Here the frequency fluctuation ΔΩ(t) appears in the argument of cosine, and dⱼₖ and φⱼₖ are respectively complex and real numbers dependent upon the pulse sequence, where j or k are spin indices. As explained earlier, ΔΩ(t) is independent of spin indices j or k.

By tuning the phase of the same pulse sequence differently, a sine modulation in cₖ can be obtained as well. In some embodiments, the calibration of ΔΩ(t) in the f₁ domain utilizes both of these scans for a given t₁, which generate the cosine and sine modulations. Two scans for a given t₁ are already necessary for the well-known frequency discrimination in the f₁ domain, thus no additional physical overhead is required. These two scans may be indexed as ‘c’ and ‘s’. The corresponding complex amplitudes, cₖ^{c} and cₖ^{s}, then can be written as:

$$\begin{matrix}{c}_{k}^{c} = {\sum }_{j}^{N} {d}_{jk} cos \{ ( {Ω}_{0 , j} + {ΔΩ}^{c} ( t ) ) {t}_{1} + {φ}_{jk} \} . & ( 9 ) \\ {c}_{k}^{s} = {\sum }_{j}^{N} {d}_{jk} sin \{ ( {Ω}_{0 , j} + {ΔΩ}^{s} ( t ) ) {t}_{1} + {φ}_{jk} \} . & ( 10 )\end{matrix}$$

where ΔΩ^{c} and ΔΩ^{s} are the frequency offsets in the two scans and quite close to each other.

Two calibration methods for obtaining the desired correct complex amplitude,

$${c}_{k , cal} ≡ {\sum }_{j}^{N} {d}_{jk} exp \{ i ( {Ω}_{0 , j} {t}_{1} + {φ}_{jk} ) \} . \qquad ( 11 )$$

can be used, in some embodiments of the present application.

Method 1 for Calibration of Larmor Frequency Drift in the f₁ Domain

From Eq. (9-11), the desired correct complex amplitude may be expressed as:

$$\frac{{c}_{k}^{c} exp ( - {iΔΩ}^{s} ( t ) {t}_{1} ) + i {c}_{k}^{s} exp ( - {iΔΩ}^{c} ( t ) {t}_{1} )}{cos \{ ( {ΔΩ}^{c} ( t ) - {ΔΩ}^{s} ( t ) ) {t}_{1} \}} = {c}_{k , cal} . \qquad ( 12 )$$

Via the f₂ domain calibration described above, the values for ΔΩ^{c}(t) and ΔΩ^{s}(t) can be estimated. The estimated values can be mathematically written as Δ\hat{Ω}^{c}(t) and Δ\hat{Ω}^{s}(t), following widely used convention. By plugging these estimated values into Eq. (12), the correct complex amplitude can be readily obtained. This step is justified because the evolution and acquisition phases for a given scan are closely placed in time. In practice, this calculation is typically performed on the time-domain signals, \hat{x}^{c}(t) and \hat{x}^{s}(t) (given by Eq. (7)], calibrated in the f₂ domain as described above.

Method 2 for Calibration of Larmor Frequency Drift in the f₁ Domain

From Eq. (9-11), the following identity holds:

cₖ^{c} exp(−iΔΩ^{c}(t)t₁)+i cᵢ^{s} exp(−iΔΩ^{s}(t)t₁)=c_{k,cal}+[f₁ noise floor term], (13)

where the f₁ noise floor term is given by

$${\sum }_{j}^{N} {d}_{jk} sin ( {ΔΩ}^{c} ( t ) - {ΔΩ}^{s} ( t ) ) {t}_{1} \times exp [ - i \{ ( {Ω}_{0 , j} + {ΔΩ}^{c} ( t ) + {ΔΩ}^{s} ( t ) ) {t}_{1} - {φ}_{jk} + \frac{π}{2} \} ] \qquad ( 14 )$$

The above f₁ noise floor term does not contribute to the deterministic NMR peak patterns but only raises the noise floor, because of the randomness of ΔΩ^{c}(t) and ΔΩ^{s}(t). Therefore, again by using the estimated values for ΔΩ^{c}(t) and ΔΩ^{s}(t) from the f₂-domain calibration on the left hand side of Eq. (13), the desired correct complex amplitude (with the additive noise floor) can be obtained.

Each of the methods described above comes with its own limitations. In Method 1, the denominator cos(Δ\hat{Ω}^{c}(t)−Δ\hat{Ω}(t))t₁ of Eq. (12) approaches zero as (Δ\hat{Ω}^{c}(t)−Δ\hat{Ω}^{s}(t))t₁ approaches π/2 (or its odd multiples). In this case, the physical background noise is significantly amplified. Thus, Method 1 is effective when (Δ\hat{Ω}^{c}(t)−Δ\hat{Ω}^{s}(t))t₁ is reasonably different from odd multiples of π/2, or when SNR is high enough to tolerate amplified noise.

The limitation of Method 2 is the f₁ noise floor term of Eq. (14). These two methods may be used together. For instance, when Method 1 becomes ineffective with (Δ\hat{Ω}^{c}(t)−Δ\hat{Ω}^{s}(t))t₁ approaching odd multiples of π/2, one can resort to Method 2.

For the f₁ calibration methods described in Eq. (12) and (13), it is noted that the multiplicand (e.g. cₖ^{c} in Eq. (12)) and the multiplier (e.g. exp(−iΔΩ^{s}(t)t₁)/cos{(ΔΩ^{c}(t)−ΔΩ^{s}(t))t₁} in Eq. (12)) are both complex numbers, and their product may not produce desirable peak shapes in 2D spectrum. Therefore, one should separate real and imaginary parts of the target time-domain signal (e.g. \hat{x}^{c}(t)) before applying the f₁ calibration methods in order to avoid multiplying two complex numbers.

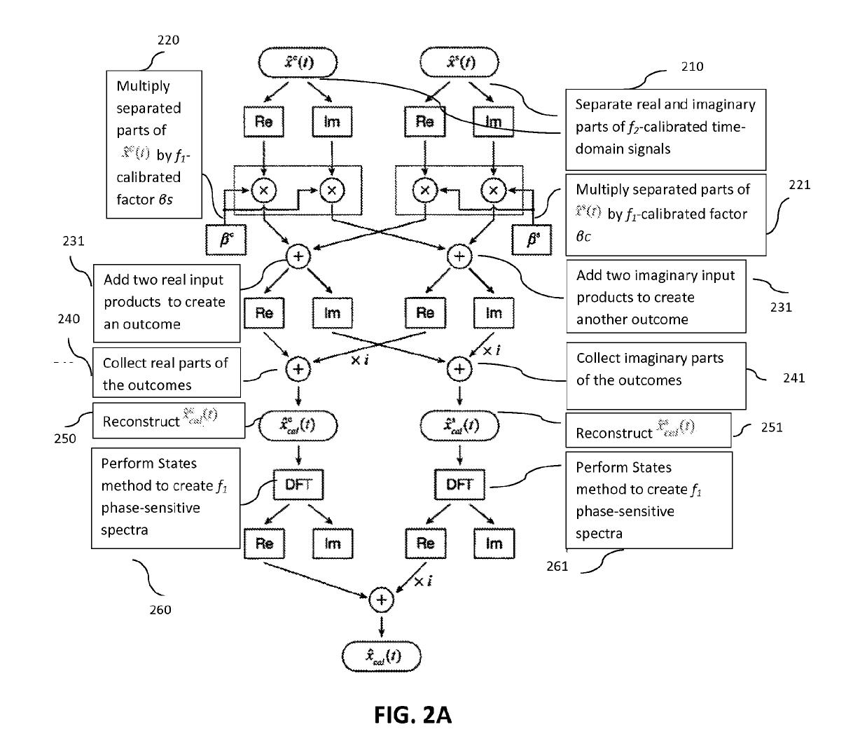

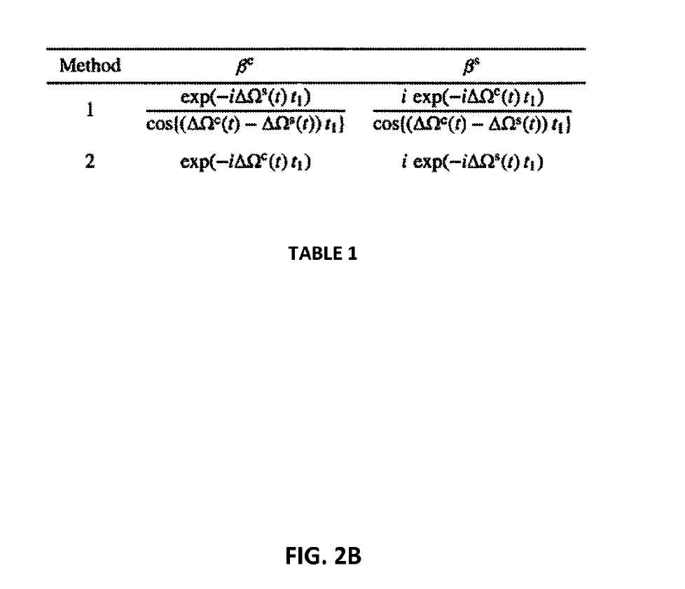

FIG. 2A provides a flowchart for a method 200 of performing non-constant frequency drift calibration in the f₁ domain, which summarizes the acts described above. FIG. 2B provides a table of f₁-calibration factors, β^{c} and β^{s}.

The method 200 includes an act 210 of separating the real and imaginary parts of the f₂-calibrated time domain target signals, \hat{x}^{c}(t) and \hat{x}^{s}(t). The method 200 further includes acts 220 and 221 of multiplying the separated parts by their respective f₁-calibration factors, β^{c} and β^{s}, which are listed in Table 1 provided in FIG. 2B. Next, the two real-input products are summed for one outcome, and the two imaginary-input products are summed for the other outcome, in acts 230 and 231. It is noted that the calibration result for the cosine version signal \hat{x}^{c}(t) is stored in the real parts of the two outcomes, and the one for the sine version signal \hat{x}^{s}(t) is stored in their imaginary parts.

In acts 240 and 241, the respective real and imaginary parts of the outcomes are collected. As a result, the desired signals, \hat{x}_{cal}^{c}(t) and \hat{x}_{cal}^{s}(t), are reconstructed in acts 250 and 251. Finally, the remaining part of the method 200 includes acts 260 and 261 of performing the States method to create the desired f₁ phase-sensitive spectra.

Experimental Results of Larmor Frequency Drift Calibration

In one exemplary embodiment of the present application, disclosed for illustrative purposes, the experimental setup for the calibration methods described above includes a 0.51-T NdFeB permanent magnet (W×D×H: 12.6×11.7×11.9 cm³; weight: 7.3 kg; Neomax Co.), a capillary tube to carry the target sample to the sensitive volume of 0.8 μL, a solenoidal coil (axial length: 1 mm) wrapping around the capillary tube (inner diameter: 1 mm), and an NMR spectrometer electronics to generate pulse sequences and acquire NMR signals. The permanent magnet is naturally exposed to the surrounding environment in a laboratory without thermal regulation. The Larmor frequency for ¹H spins with this magnet is 21.84 MHz. In some embodiments, the measurement data may be processed using the Numpy/Scipy library for the Python language.

Many other types of experimental setups are possible, and the above example is provided only for illustrative purposes.

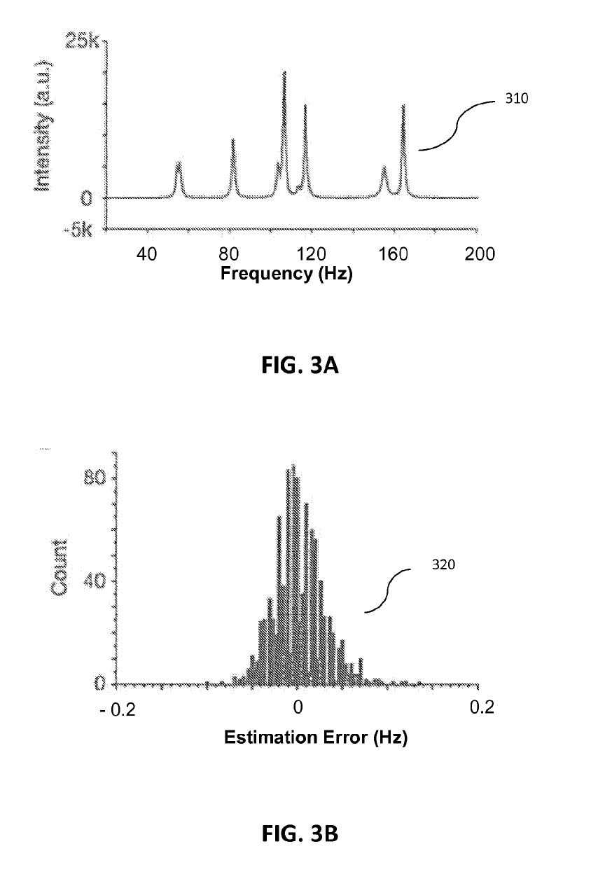

FIGS. 3A-3B show the simulation results of calibration for the O^{th} order (constant) Larmor frequency drift ΔΩ₀. The non-constant term ΔΩ₁t is assumed to be zero. FIG. 3A shows the reference 1D spectrum 310. In the illustrated embodiments, 1000 target spectra were populated to be calibrated, and the estimation errors of calibration were calculated. For each target spectrum, ΔΩ₀ was randomly chosen. Furthermore, the peak intensities of each target spectrum were randomly modulated to emulate 2D NMR where each peak's intensity is modulated by spin couplings. As a distance measuring function, the Hellinger distance was used. The Hellinger distance between two given probability densities f(ω) and g(ω) is written as:

D(f(ω),g(ω))=\sqrt{1−∫\sqrt{f(ω)g(ω)}dw} (15)

FIG. 3B is a plot of the estimation error 320. After 1000 calibrations, the mean estimation error of 0.0022 Hz was obtained, with standard deviation of 0.028 Hz where minimum half-maximum-full-width is 1.3 Hz, as illustrated in FIG. 3B.

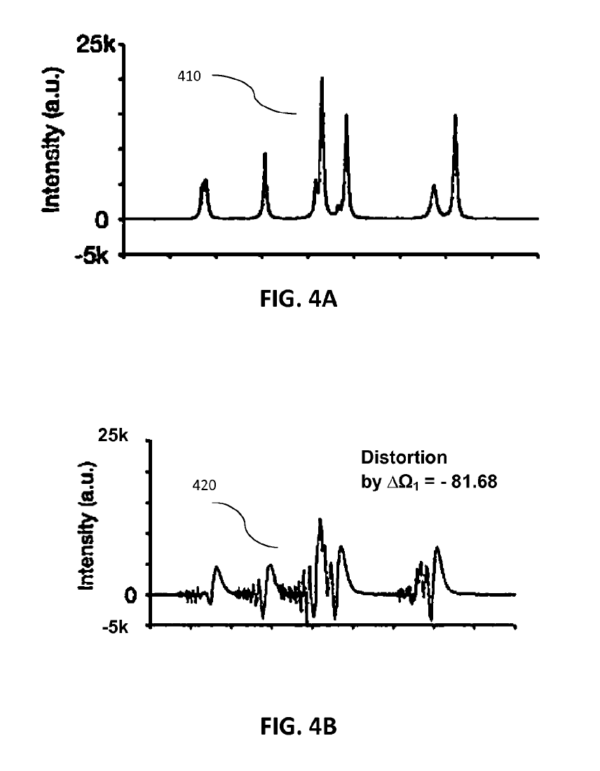

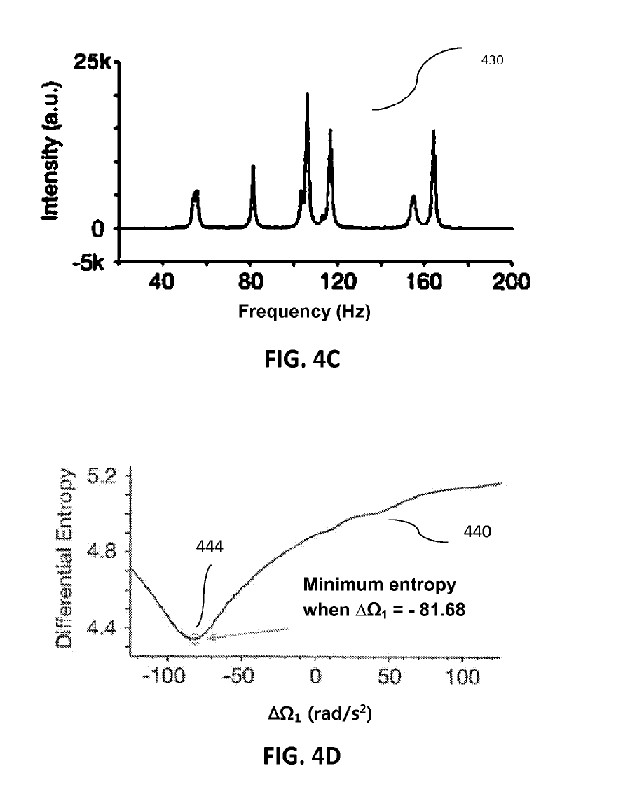

FIGS. 4A-4D show the simulation results of Larmor frequency drift calibration for the linear (non-constant) term ΔΩ₁t, applied to an 1D NMR spectrum. FIG. 4A is a plot 410 of the original intended NMR spectrum [symbol] e{X(ω)}. This graph is arbitrarily created to show the effectiveness of this method. FIG. 4B is a plot 420 of the degraded NMR spectrum [symbol] e[Y(ω)]= [symbol] e[X(ω)·W(ω)], where ΔΩ₁=20π.

FIG. 4C is a plot 430 of the restored spectrum [symbol] e[X(ω)], after ΔΩ₁ calibration by entropy minimization. The intended NMR spectrum is well restored in this figure without any sign of degradation. FIG. 4D is a plot 440 of the differential entropy with respect to the calibration values of ΔΩ₁. By changing the values of ΔΩ₁ for w⁻¹(t)=exp[−iΔΩ₁t], one can find the minimum entropy 444 of f_{Y:ΔΩ}_{₁}(ω), which is at ΔΩ₁=20π as shown in FIG. 4D.

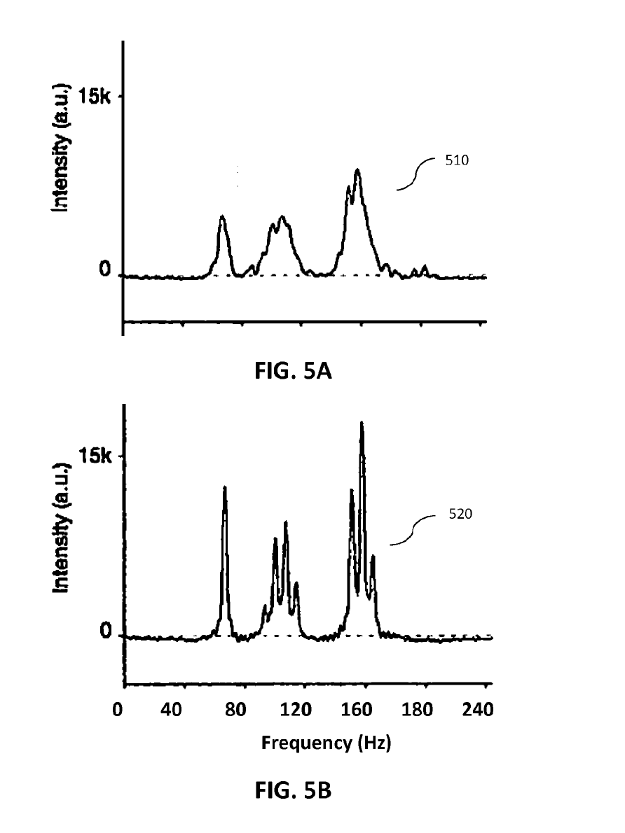

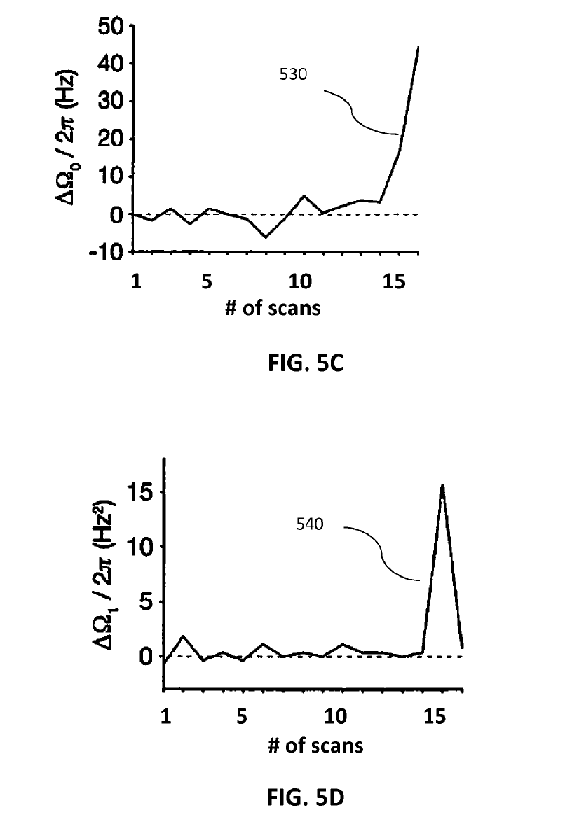

FIGS. 5A-5D illustrate the experimental results of ΔΩ(t) calibration for 1D NMR spectra of ethanol. In the illustrated embodiments, 16 identical free-induction-decay experiments on ethanol sample were performed under the influence of the field fluctuation. First, without calibration, measured time-domain signals are averaged and its Fourier transform 510 is plotted, as shown in FIG. 5A. Due to the effect of the field fluctuation, each scan is slightly shifted in the frequency domain and consequently the average of 16 signals produces a blurry spectrum. After the f₂-domain calibration is performed for the 16 signals, their spectra are all reshaped and lined up altogether to create a nicely averaged NMR spectrum 520 of ethanol, as shown in FIG. 5B. In the process, the constant and linear terms (ΔΩ₀ and ΔΩ₁t) of the frequency fluctuation ΔΩ(t) are estimated and respectfully plotted in FIG. 5C and 5D, indicated with reference numerals 530 and 540.

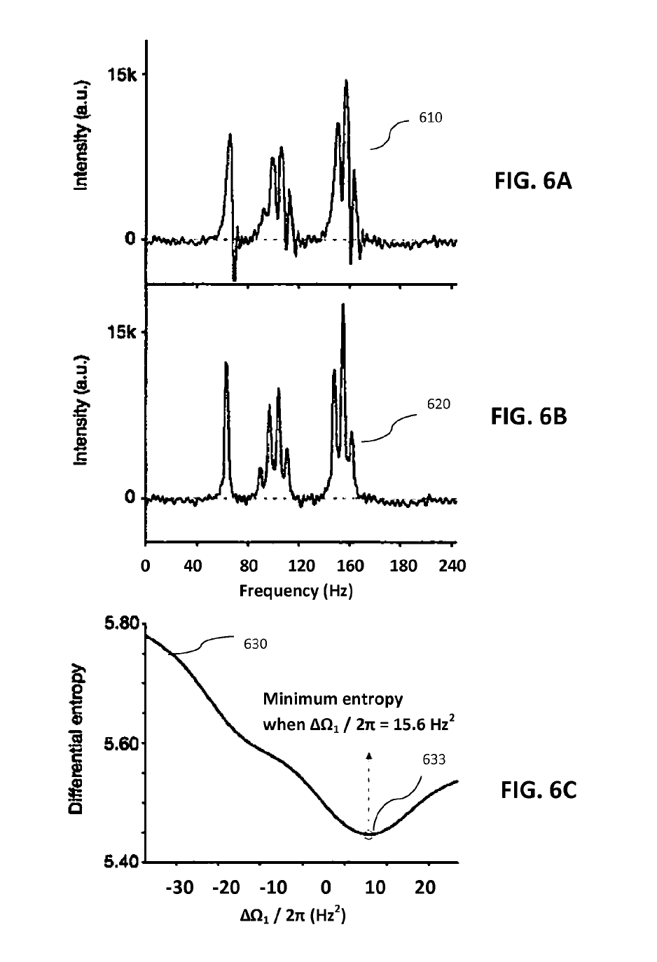

FIGS. 6A-6C illustrate the results of Larmor frequency drift calibration of the linear term ΔΩ₁t for 1D spectra of ethanol. It is noted that the scan number 15 has significantly larger linear term ΔΩ₁ than other scans in FIG. 5D. Due to the effect of that fluctuation, one can observe that the 1D spectrum 610 of the 15^{th}-scan signal, shown in FIG. 6A, has visibly distorted the line-shapes. The right side of each peak group looks especially crooked.

FIG. 6C is a plot 630 of the distribution of differential entropy with respect to the estimate of ΔΩ₁. Calibration is performed on the 1D spectrum using the estimated value of ΔΩ₁ by finding the minimum entropy point 633, shown in FIG. 6C. As a result, the 1D spectrum 620 of ethanol is successfully recovered in FIG. 6B, as can be seen by comparing the spectrum 620 in FIG. 6B with the spectrum in FIG. 6A.

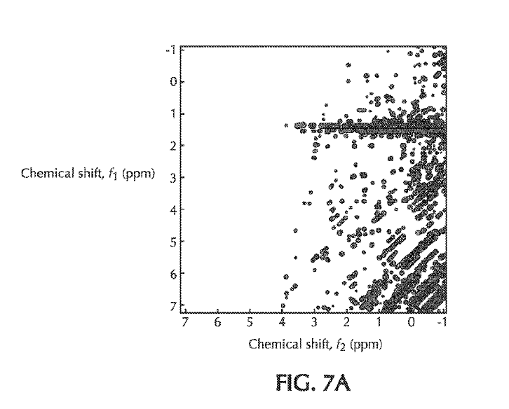

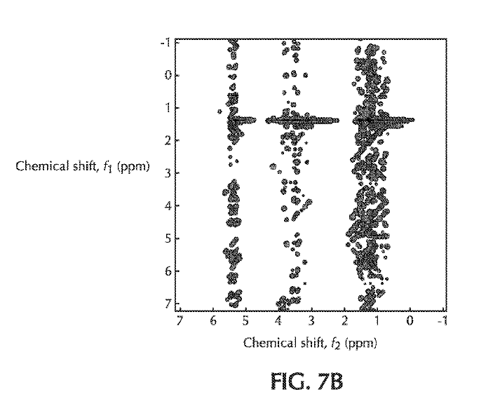

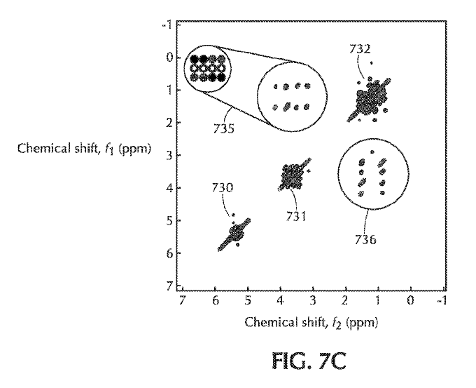

FIGS. 7A-7C illustrate the experimental results of constant Larmor frequency shift calibration for 2D COSY performed on an ethanol sample under the influence of the field fluctuations. In the illustrated embodiments, 400 scans were acquired with a t₁ increment of 2 ms from 0 s to 200 ms. For each t₁ value, 4-cycle phase cycling are performed.

In the illustrated embodiment, the States method was used for quadrature detection in f₁ domain. FIG. 7A illustrates the 2D COSY spectrum of ethanol without any frequency calibrations. Before proper calibration is applied, only noisy and unrecognizable 2D spectrum can be seen. FIG. 7B shows the resulting spectrum after f₂ calibration is first performed on the acquired data. As seen in FIG. 7B, peaks are clustered into three groups along the f₂ axis.

FIG. 7C shows the resulting 2D COSY spectrum after both f₂ and f₁ calibration have been performed. As seen in FIG. 7C, a clear peak pattern emerges: Three diagonal peak groups 730, 731, and 732 are seen coming from protons in the hydroxyl, methylene, and methyl group, from left to right. There are two cross peak groups 735 and 736 in the circled area that indicate the existence of J-coupling between the methylene and methyl groups. Zooming in the cross peaks, one can also notice that they show theoretically predicted peak pattern. In this particular embodiment, the Hellinger distance in Eq. (15) is used for Eq. (6) to measure the statistical distance between two densities to estimate constant frequency drift ΔΩ₀ in the frequency fluctuation. In the illustrated embodiment, ΔΩ₁ calibration was not used for the 2D spectrum since it was found not to be as effective as in the 1D spectrum. For f₁ calibration, both Method 1 and Method 2 were used. Method 1 can be used in general cases except when the denominator of the f₁ calibration factors for Method 1 (provided in the table in FIG. 2B) approaches 0, to avoid excessive background noise amplification.

In sum, systems and methods have been described for Larmor frequency calibration in NMR systems. An NMR spectrometer, in accordance with some embodiments of the present application, includes a calibration system. The calibration system is configured to calibrate, in an f₂ frequency domain one or more NMR signals, so as to remove from the NMR signal the effects of temperature-induced frequency fluctuations in the f₂ domain. The calibration system is also configured to further calibrate the f₂ calibrated NMR signal in an f₁ frequency domain (which is a Fourier transform of the t₁ domain), thereby removing the effects of temporal frequency drifts during an evolution phase of the NMR scan. The calibration system may be configured to calibrate the NMR signal in the f₂ frequency domain by estimating the value of an offset ΔΩ in the Larmor frequencies of the spins in the sample, then removing the offset ΔΩ from the NMR signal using the estimated value.

The calibration system may be configured to further calibrate in the f₁ domain by: obtaining a cosine modulation and a sine modulation in the complex amplitudes of the f₂ calibrated NMR signal; estimating the frequency offsets in the cosine modulated and sine modulated amplitudes; and using these estimated frequency offsets to recover, from the cosine modulated and sine modulated amplitudes, the complex amplitudes of an NMR signal that is calibrated in both the f₁ and the f₂ domains.

The signal-processing techniques presented in this application remove the effect of magnetic field fluctuations (which may be assumed to be either constant or non-constant), which plague high-resolution NMR spectra. The constant shift in the field between two NMR scans is computed by measuring the statistical distance between the two NMR spectra. The field linearly changing with time t is estimated by finding the minimum information entropy of the given spectrum. Also, the field fluctuation effect in the evolution phase of 2D NMR is removed by correcting the amplitude and phase of each NMR spin signal. Using these techniques, poor ID or 2D NMR spectra in experiments resulting from unstable fields are nicely repaired. The above-described field fluctuation calibration techniques are found to be particularly useful for portable NMR spectroscopy systems with permanent magnets, the fields of which are unstable due to their large temperature dependency.

In principle the methods and systems described above can be readily generalized to 3D NMR, even though in many applications (such as applications using permanent magnets), an actual implementation of 3D NMR may be quite impractical because 3D NMR would require an undue amount of time, given the low magnetic field strength of permanent magnets. A 3D generalization of the above methods and systems would involve another evolution period (corresponding to the above-discussed indirect time t₁ in 2D NMR), which cosine/sine modulates the 2D NMR spectra, by analogy to the above-described mechanics of 2D NMR. Using the estimated f₂ frequency drift for each scan, one can calibrate the frequency drift in the 3D evolution period.

The methods and systems described above can be also used to calibrate frequency drift in NMR relaxometry experiments, i.e. these calibrations can be carried out by an NMR relaxometer. Some relaxometry experiments such as 2D relaxometry (e.g. diffusion-T₂ distribution analysis) requires multiple scans through which magnetic field can drift significantly. There are two methods to adjust frequency of relaxometry experiments. First, one can acquire a separate 1D NMR spectrum between each relaxometry scan. Second, one can acquire a spectrum directly from each relaxometry scan. If each scan contains a plurality of echoes (e.g. CPMG), one can take a spectrum from each echo. Based on these spectra whether they are acquired from a separate 1D NMR scan or from a relaxometry experiment itself, one can easily adjust the NMR excitation/acquisition frequency or shift the frequency of the following relaxometry experiment data using signal processing. The methods and systems described above can be also used to calibrate frequency drift in NMR experiments that does not use permanent magnets. If fluctuation information is known (e.g., 60 Hz power line modulation), one can calibrate out the fluctuation by setting up a few unknown parameters (e.g. parameter a and b for a cos(2*pi*60t+b) and by estimating those parameters using non-constant frequency drift calibration methods.

A processing system may be integrated in, or connected to, the above-described calibration system. The processing system is configured to perform the above-mentioned computations, as well as other computations described in more detail below. The processing system is configured to implement the methods, systems, and algorithms described in the present application. The processing system may include, or may consist of, any type of microprocessor, nanoprocessor, microchip, or nanochip. The processing system may be selectively configured and/or activated by a computer program stored therein. The processing system may include a computer-usable medium in which such a computer program may be stored, to implement the methods and systems described above. The computer-usable medium may have stored therein computer-usable instructions for the processing system. The methods and systems in the present application have not been described with reference to any particular programming language. Thus, a variety of platforms and programming languages may be used to implement the teachings of the present application.

The components, steps, features, objects, benefits and advantages that have been disclosed are merely illustrative. None of them, nor the discussions relating to them, are intended to limit the scope of protection in any way. Numerous other embodiments are also contemplated, including embodiments that have fewer, additional, and/or different components, steps, features, objects, benefits and advantages. Nothing that has been stated or illustrated is intended to cause a dedication of any component, step, feature, object, benefit, advantage, or equivalent to the public. While the specification describes particular embodiments of the present disclosure, those of ordinary skill can devise variations of the present disclosure without departing from the inventive concepts disclosed in the disclosure. In the present application, reference to an element in the singular is not intended to mean “one and only one” unless specifically so stated, but rather “one or more.” All structural and functional equivalents to the elements of the various embodiments described throughout this disclosure, known or later come to be known to those of ordinary skill in the art, are expressly incorporated herein by reference.

What is claimed is:

1. A system comprising:
a calibration system configured to remove in an f₂ frequency domain the effects of a fluctuation ΔΩ(t) in Larmor frequencies of a plurality N of nuclear spins in a sample, from an NMR signal acquired from the sample during an acquisition time t₂ of an NMR scan having an evolution time t₁, thereby generating an f₂-calibrated NMR signal;
wherein the calibration system is further configured to remove from the f₂-calibrated NMR signal the effects of ΔΩ(t) in an f₁ domain, thereby additionally calibrating the f₂-calibrated NMR signal in the f₁ domain;
wherein f₁ is a Fourier transform of the evolution time t₁, and f₂ is a Fourier transform of the acquisition time t₂.

2. The system of claim 1, wherein the calibration system is configured to remove in an f₂ frequency domain the effects of a fluctuation ΔΩ(t) in the Larmor frequencies, by estimating the value of ΔΩ(t), then removing the fluctuation ΔΩ(t) by cancelling out the estimated value from the NMR signal.

3. The system of claim 2,
wherein the calibration system is configured to approximate the Larmor frequency Ωₖ(t) of the k-th spin (k=1 . . . N) as a sum of an intended Larmor frequency Ω_{0,k} for the k-th spin in the absence of fluctuations in the magnetic field B₀, plus the fluctuation ΔΩ(t):
Ωₖ(t)=γ(1+δₖ)·(B₀+ΔB₀(t)+εₖ≈γB₀(1+δₖ)+εₖ+γΔB₀(t)=Ω_{0,k}+ΔΩ(t),
where
k is a summation index for the spins of the sample, representing a summation (k=1, . . . , N) over the plurality N of spins;
γ is the gyromagnetic ratio;
B₀ is the static magnetic field in the absence of any temperature-dependent fluctuations of the field;
ΔB₀(t) is the temporal fluctuation in the magnetic field;
δₖ is the chemical shift for the k-th spin; and
εₖ is the frequency offset due to J-coupling;

4. The system of claim 3, wherein the calibration system is configured to approximate the frequency fluctuation ΔΩ(t) as a sum of a constant frequency drift ΔΩ₀, and a non-constant frequency modulation term ΔΩ₁t; and
wherein the calibration system is further configured to estimate ΔΩ(t) by estimating the constant frequency drift ΔΩ₀ and the non-constant frequency modulation term ΔΩ₁t.

5. The system of claim 4, wherein the act of calibrating the NMR signal in the f₂ frequency domain comprises:
modeling a time dependence of the NMR signal under the influence of the frequency fluctuation ΔΩ(t) with a mathematical expression given by:
$$\begin{matrix}y ( t ) = {\sum }_{k}^{N} {c}_{k} exp \{ ( {iΩ}_{k} ( t ) - {λ}_{k} ) t \} \\ = exp [ iΔΩ ( t ) t ] \times {\sum }_{k}^{N} {c}_{k} exp \{ ( {iΩ}_{0 , k} ( t ) - {λ}_{k} ) t \} \\ = w ( t ) \times x ( t ) ,\end{matrix}$$
where k is a summation index for the spins of the sample, representing a summation (k=1, . . . , N) over the plurality N of spins, y(t) represents the measured NMR signal, x(t) represents an unaffected NMR signal, w(t) represents a phase-modulation function of ΔΩ(t), cₖ is a complex amplitude representing the signal strength and phase for the k-th spin, and λₖ is an exponential decay rate for the k-th spin.

6. The system of claim 5, wherein the act of estimating the constant frequency drift ΔΩ₀ comprises:
measuring a statistical distance between probability densities for the measured NMR signal and a reference signal, while shifting the frequency of the measured signal, and
finding a minimum of said statistical distance to obtain the estimated value Δ\hat{Ω}₀ whose mathematical expression is given by:
$$Δ {\hat{Ω}}_{0} = arg {min}_{{ΔΩ}_{0}} D ( {f}_{Y ; {ΔΩ}_{0}} ( ω ) , {f}_{{X}_{R}} ( ω ) ) ;$$
wherein D(·, ·) is a distance measuring function; and
wherein f_{Y:ΔΩ}_{₀} and f_{X}_{_{R}}(ω) are probability densities for the measured signal y(t) with its frequency shifted by −ΔΩ₀ and the reference signal x_{R}(t), respectively, the probability density f_{Y}(ω) being a normalized energy spectral density having a mathematical expression given by:
$${f}_{Y} ( ω ) = \frac{{\vert T ( ω ) \vert}^{2}}{{\int }_{- ∞}^{∞} {\vert Y ( ω ) \vert}^{2} d ω / 2 π} = \frac{{\vert ( W * X ) ( ω ) \vert}^{2}}{{\int }_{- ∞}^{∞} {\vert ( W * X ) ( ω ) \vert}^{2} d ω / 2 π} ,$$
where Y(ω), W(ω) and X(ω) are the Fourier transforms of y(t), w(t), and x(t), respectively, and the symbol * represents the convolution operator.

7. The system of claim 6, wherein the distance measuring function comprises a Hellinger distance having a mathematical expression given by:
D(f(ω),g(ω))=\sqrt{1−∫\sqrt{f(ω)g(ω)}dw}.

8. The system of claim 4, wherein the act of estimating the non-constant frequency modulation term ΔΩ₁t comprises:
assuming w(t) to be an exponential function exp(iΔΩ₁t);
using an information entropy function h(f_{Y}(ω))=−∫f_{Y}(ω)ln f_{Y}(ω)dω/2π as a measure of amount of uncertainty in observing the energies of the nuclear spins in the sample, and thus a likelihood function to estimate ΔΩ₁; and
finding a minimum of said entropy to obtain the estimated value Δ\hat{Ω}₁ whose mathematical expression is given by:
$$Δ {\hat{Ω}}_{1} = arg {min}_{{ΔΩ}_{1}} h ( {f}_{Y ; {ΔΩ}_{1}} ( ω ) ) ,$$
where f_{Y:ΔΩ}_{₁}(ω) is a probability density for y(t)·w⁻¹(t), the probability density being a normalized energy spectral function having a mathematical expression given by:
$${f}_{Y} ( ω ) = \frac{{\vert Y ( ω ) \vert}^{2}}{{\int }_{- ∞}^{∞} {\vert Y ( ω ) \vert}^{2} d ω / 2 π} = \frac{{\vert ( W * X ) ( ω ) \vert}^{2}}{{\int }_{- ∞}^{∞} {\vert ( W * X ) ( ω ) \vert}^{2} d ω / 2 π} ,$$
where Y(ω), W(ω) and X(ω) are the Fourier transforms of y(t), w(t), and x(t), respectively, and the symbol * represents the convolution operator.

9. The system of claim 1, wherein the calibration system is configured to further calibrate in the f₁ domain for 2D (two dimensional) NMR by:
obtaining a cosine modulation and a sine modulation in the complex amplitudes by respectively different tuning of the phase of an RF pulse sequence applied to the sample during the NMR scan;
estimating the frequency offsets and in the cosine modulated and sine modulated amplitudes; and
using the estimated frequency offsets to recover, from the cosine modulated and sine modulated amplitudes, the complex amplitudes of an NMR signal that is calibrated in both the f₁ and f₂ domains.

10. The system of claim 9,
wherein a mathematical expression for the cosine modulated amplitudes is given by:
$${c}_{k}^{c} = {\sum }_{j}^{N} {d}_{jk} cos \{ ( {Ω}_{0 , j} + {ΔΩ}^{c} ( t ) ) {t}_{1} + {φ}_{jk} \} ,$$
and
wherein a mathematical expression for the sine modulated amplitudes cₖ^{s} is given by:
$${c}_{k}^{s} = {\sum }_{j}^{N} {d}_{jk} sin \{ ( {Ω}_{0 , j} + {ΔΩ}^{s} ( t ) ) {t}_{1} + {φ}_{jk} \} .$$

11. The system of claim 10, wherein the calibration system is configured to recover the complex amplitudes from the cosine modulated and sine modulated amplitudes by:
mathematically expressing the complex amplitudes c_{k,cal} as:
$${c}_{k , cal} ≡ {\sum }_{j}^{N} {d}_{jk} exp \{ i ( {Ω}_{0 , j} {t}_{1} + {φ}_{jk} ) \} ,$$
and
substituting the estimated values for the cosine modulated and sine modulated amplitudes, in a mathematical identity that expresses c_{k,cal} in terms of the frequency offsets in the cosine and sine modulation,
wherein the mathematical identity is given by:
$$\frac{{c}_{k}^{c} exp ( - {iΔΩ}^{s} ( t ) {t}_{1} ) + i {c}_{k}^{s} exp ( - {iΔΩ}^{c} ( t ) {t}_{1} )}{cos \{ ( {ΔΩ}^{c} ( t ) - {ΔΩ}^{s} ( t ) ) {t}_{1} \}} = {c}_{k , cal} .$$

12. The system of claim 10, wherein the calibration system is configured to recover the complex amplitudes from the cosine modulated and sine modulated amplitudes by:
expressing the complex amplitudes in terms of the cosine modulated and sine modulated amplitudes cₖ^{c} and cₖ^{s}, and a noise floor term, using a mathematical identity;
wherein the mathematical equation is given by:
cₖ^{c} exp(−iΔΩ^{c}(t)t₁)=i cₖ^{s} exp(−iΔΩ^{s}(t)t₁)=c_{k,cal}+[f₁ noise floor term],
and substituting the estimated values for cₖ^{c} and cₖ^{s} in the mathematical identity; where the noise floor term is given by:
$${\sum }_{j}^{N} {d}_{jk} sin ( {ΔΩ}^{c} ( t ) - {ΔΩ}^{s} ( t ) ) {t}_{1} \times exp [ - i \{ ( {Ω}_{0 , j} + {ΔΩ}^{c} ( t ) + {ΔΩ}^{s} ( t ) ) {t}_{1} - {φ}_{jk} + \frac{π}{2} \} ] .$$

13. A method comprising:
estimating the value of a frequency fluctuation ΔΩ(t) in the Larmor frequencies of a plurality N of nuclear spins in a sample, in a f₂ frequency domain, for an NMR signal acquired from the sample during an acquisition time t₂ of an NMR scan having an evolution time t₁;
removing the fluctuation ΔΩ(t) from the NMR signal using the estimated value, thereby generating an f₂ calibrated NMR signal from which the temperature-induced frequency fluctuations in the f₂ domain have been removed; and
further calibrating the f₂ calibrated NMR signal in an f₁ frequency domain for 2D NMR, thereby removing from the signal the effects of temporal frequency drifts during the evolution phase of the NMR scan;
wherein the f₂ domain is a Fourier transform of the t domain, and the f₁ domain is a Fourier transform of the t₁ domain.

14. The method of claim 13,
wherein the act of calibrating the NMR signal in the f₂ frequency domain further comprises:
approximating the frequency fluctuation ΔΩ(t) as a sum of a constant frequency drift ΔΩ₀, and a non-constant frequency modulation term ΔΩ₁t; and
estimating the constant frequency drift and non-constant frequency modulation terms.

15. The method of claim 14, wherein the act of estimating the constant frequency drift ΔΩ₀ comprises:
measuring a statistical distance between probability densities for the measured NMR signal and a reference signal, while shifting the frequency of the measured signal, and
finding a minimum of said statistical distance to obtain the estimated value Δ\hat{Ω}₀.

16. The method of claim 14, wherein the act of estimating the non-constant frequency drift ΔΩ₁t comprises:
assuming w(t) to be an exponential function exp(iΔΩ₁t);
using an information entropy function as a measure of amount of uncertainty in observing the energies of the nuclear spins in the sample, and thus a likelihood function to estimate ΔΩ₁; and
finding a minimum of said entropy to obtain the estimated value Δ\hat{Ω}₁.

17. The method of claim 13, wherein the act of further calibrating in the f₁ domain in 2D NMR comprises:
obtaining a cosine modulation and a sine modulation in the complex amplitudes by respectively different tuning of the phase of an RF pulse sequence applied to the sample during the NMR scan;
estimating the frequency offsets and in the cosine modulated and sine modulated amplitudes; and
using the estimated frequency offsets to recover, from the cosine modulated and sine modulated amplitudes, the complex amplitudes of an NMR signal that is calibrated in both the f₁ and f₂ domains.

18. An NMR system comprising a calibration system;
wherein the calibration system is configured to remove in an f₂ frequency domain the effects of a fluctuation ΔΩ(t) in Larmor frequencies of a plurality N of nuclear spins in a sample, from an NMR signal acquired from the sample during an acquisition time t₂ of an NMR scan having an evolution time t₁, so as to generate an f₂-calibrated NMR signal; and
wherein the calibration system is configured to further calibrate the f₂-calibrated NMR signal in an f₁ frequency domain in 2D NMR;
where f₂ is a Fourier transform of the t₂ domain, and f₁ is a Fourier transform of the t₁ domain.

19. The NMR system of claim 18, wherein the calibration system is configured to remove in an f₂ frequency domain the effects of a fluctuation ΔΩ(t) in the Larmor frequencies by:
estimating the value of a frequency fluctuation ΔΩ(t) in the Larmor frequencies of the spins of the sample; and
removing the fluctuation ΔΩ(t) from the NMR signal using the estimated value, thereby generating an f₂ calibrated NMR signal from which the effects of the frequency fluctuations in the f₂ domain have been removed.

20. The NMR system of claim 19, wherein the calibration system is configured to approximate the frequency fluctuation ΔΩ(t) as a sum of a constant frequency drift ΔΩ₀, and a non-constant frequency modulation term ΔΩ₁t; and
wherein the calibration system is further configured to estimate ΔΩ(t) by estimating the constant frequency drift ΔΩ₀ and the non-constant frequency modulation term ΔΩ₁t.

21. The NMR system of claim 18, wherein the NMR system comprises one of: an NMR spectrometer; and an NMR relaxometer.
